(19) United States
(12) Patent Application Publication
(10) Pub. No.: US 2026/0212921 A1
(43) Pub. Date: Jul. 23, 2026

(54) WORD-LINE DRIVER UTILIZING WORD-LINE VOLTAGE SUPPRESSION FOR READ ASSIST

(71) Applicant: TAIWAN SEMICONDUCTOR MANUFACTURING COMPANY LTD, HSINCHU (TW)

(72) Inventors: AYUMU YAMADA, HSINCHU (TW); RYOTA WATANABE, HSINCHU (TW)

(21) Appl. No.: 19/034,630

(22) Filed: Jan. 23, 2025

(51) Int. Cl. G11C 11/418

(52) U.S. Cl. CPC G11C 11/418

(57) ABSTRACT

A word-line driver is provided, which includes an input stage, a driving stage, a supplementary voltage pull-up device, and a switch device. The input stage receives an activation signal. The driving stage generates an output signal at an output terminal of the word-line driver. The supplementary voltage pull-up device operates with the driving stage to pull up the output signal to a power supply voltage in response to a first enable signal in a first logic state. The switch device pulls down the output signal to a reference voltage in response to the first enable signal in a second logic state complementary to the first logic state. The output signal swings within first and second voltage domains in response to the first enable signal in the first logic state and the second logic state, respectively. The second voltage domain is wider than the first voltage domain.

### BACKGROUND

Static random access memory (SRAM) is a type of volatile semiconductor memory that stores data bits using bistable circuitry that does not need refreshing. An SRAM cell may be referred to as a bit cell because it stores one bit of information, represented by the logic state of two cross coupled inverters. Memory arrays include multiple bit cells arranged in rows and columns. Each bit cell in a memory array typically includes connections to a power supply voltage and to a reference voltage. Logic signals on bit lines control reading from and writing to a bit cell, with a word line controlling connections of the bit lines to the inverters, which otherwise float. A word line may be coupled to the bit cells in a row of a memory array, with different word lines provided for different rows.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1A is a block diagram of a memory device in accordance with an embodiment of the disclosure.

FIG. 1B illustrates a schematic symbol of the word-line driver in FIG. 1A.

FIGS. 2A to 2D are schematic diagrams of a word-line driver in accordance with some embodiments of the present disclosure.

FIG. 3A is a schematic diagram of a word-line driver coupled to a memory cell in accordance with the embodiment of FIG. 2A.

FIG. 3B is a waveform diagram of various signals in FIG. 3A.

FIG. 3C is a diagram illustrating an equivalent circuit of the word-line driver in accordance with some embodiments of the present disclosure.

FIG. 3D is a diagram illustrating the relationship between the input voltage and output voltage of the equivalent circuit in FIG. 3C.

FIG. 4A is a schematic diagram illustrating an equivalent circuit of the word-line driver in accordance with some embodiments of the present disclosure.

FIG. 4B is a schematic diagram of the simplified equivalent circuit of the word-line driver in FIG. 4A.

FIG. 5A is a diagram illustrating the relationship between the value ln(kᵣ) and the suppression voltage in accordance with some embodiments of the present disclosure.

FIG. 5B is a diagram illustrating the relationship between the threshold voltage V_{THn} and the suppression voltage in accordance with some embodiments of the present disclosure.

FIG. 5C is a diagram illustrating the relationship between the threshold voltage |V_{THp}| and the suppression voltage in accordance with some embodiments of the present disclosure.

FIGS. 6A to 6D are schematic diagrams of a word-line driver in accordance with still some embodiments of the present disclosure.

FIG. 7A is a schematic diagram of a word-line driver coupled to a memory cell in accordance with the embodiment of FIG. 6A.

FIG. 7B is a waveform diagram of various signals in FIG. 7A.

FIG. 8A is a block diagram of a word-line driver in accordance with still some embodiments of the present disclosure.

FIG. 8B is a waveform diagram of various signals within the word-line driver in FIG. 8A.

FIG. 9A is a block diagram of a word-line driver in accordance with still some embodiments of the present disclosure.

FIG. 9B is a waveform diagram of various signals within the word-line driver in FIG. 9A.

FIG. 10A is a block diagram of a word-line driver in accordance with still some embodiments of the present disclosure.

FIG. 10B is a waveform of the Schmitt trigger in FIG. 10A.

FIG. 10C is a waveform diagram of various signals within the word-line driver in FIG. 10A for the overshoot case.

FIG. 10D is another waveform diagram of various signals within the word-line driver in FIG. 10A for the overdamped case.

FIG. 11A is a block diagram of a word-line driver in accordance with still some embodiments of the present disclosure.

FIG. 11B is a waveform diagram of various signals within the word-line driver in FIG. 11A for the overshoot case.

FIG. 11C is another waveform diagram of various signals within the word-line driver in FIG. 11A for the overdamped case.

FIG. 12 is a flowchart of a method for operating a word-line driver in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

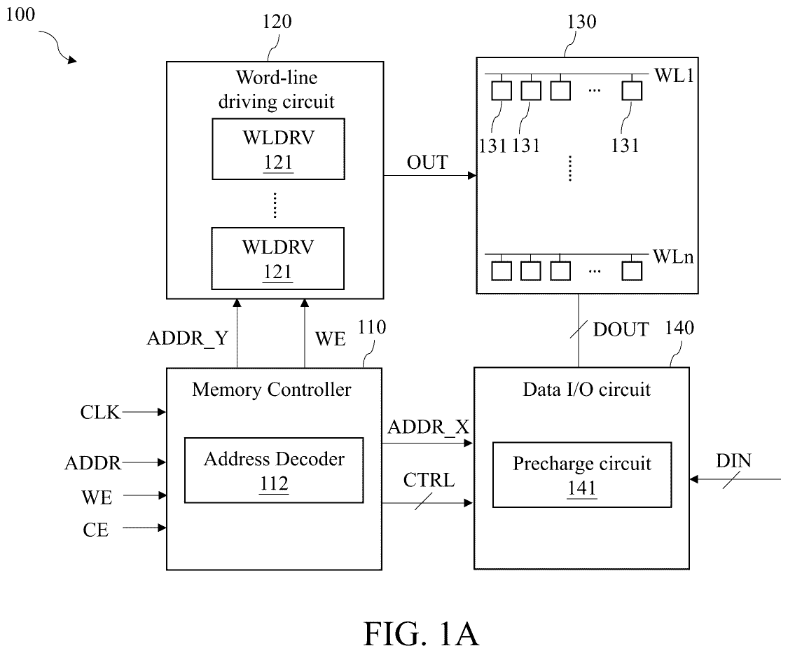

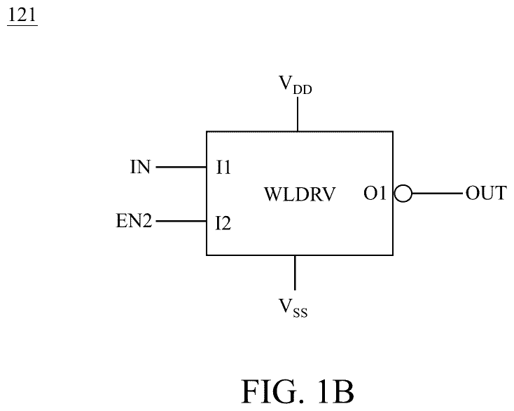

FIG. 1A is a block diagram of a memory device in accordance with an embodiment of the disclosure. FIG. 1B illustrates a schematic symbol of the word-line driver in FIG. 1A.

In some embodiments, the memory device 100 may be implemented as a standalone memory chip, or be integrated into an integrated circuit or a system-on-chip (SoC). As shown in FIG. 1A, the memory device 100 may include a memory controller 110, a word-line driving circuit 120, a memory array 130, and a data input/output (I/O) circuit 140. The memory controller 110 may be configured to receive a clock signal CLK and an input memory command, and decode the input memory command to generate a decoded row address signal ADDR_Y and a decoded column address signal ADDR_X. In some embodiments, the input memory command may include an address signal ADDR, a chip enable signal CE, and a write enable signal WE. In some embodiments, each of the chip enable signal CE and the write enable signal WE may be a low-active signal a high-active signal for the memory cells 131 with low-active or high-active word line.

In some embodiments, the word-line driving circuit 120 may be configured to assert one of the word lines of the memory array 130 in response to the decoded row address signal ADDR_Y, thereby activating one word line of the memory array 130.

In some embodiments, the memory array 130 may include a plurality of memory cells 131 arranged in a two-dimensional array. The memory cells 131 within the memory array 130 are controlled by a plurality of word lines WL (e.g., WL1 to WLn) and bit lines BL/BLB (e.g., m bit lines pairs from BL[1]/BLB[1] to BL[m]/BLB[m], not shown in FIG. 1A). In some embodiments, the data I/O circuit 140 may include a plurality of I/O pads (not shown) that correspond to the precharge circuits 141. The precharge circuits 141 may correspond to the memory cells 131 on the bit line pairs BL[1]/BLB[1] to BL[m]/BLB[m]. The memory cells 131 on the selected word line WL are activated, and the precharge circuits 141 is configured to precharge, based on the decoded column address ADDR_X and control signal CTRL generated by the memory controller 110, the voltage level of the selected bit line BL/BLB corresponding to the activated memory cells 131 to a predetermined voltage level before performing a write operation or a read operation to the activated memory cells 131, such as V_{DD} or V_{SS}, where V_{DD} and V_{SS} denotes a power supply voltage and a reference voltage, respectively. It should be noted that the memory cell 131 on the selected word line WL and the selected bit line BL/BLB can pass the data therein to the data I/O circuit 140, or receive data to be written (e.g., data signal DIN) to the selected memory cell 131 from the data I/O circuit 140.

In some embodiments, when the chip enable signal CE is in the high logic state (e.g., “1”), the memory device 100 is disabled. When the chip enable signal CE is in the low logic state (e.g., “0”), the memory device 100 is activated, and the memory controller 110 may receive the other input signals to perform a read operation or a write operation. For example, when the chip enable signal CE and write enable signal WE are both in the low logic state, the memory device 100 performs a write operation, such as writing the data signal DIN to the activated memory cell on the selected word line and bit line. When the chip enable signal CE and the write enable signal WE are in the low logic state and the high logic state, respectively, the memory device 100 performs a read operation, such as sensing the data signal DATA read from the activated memory cell on the selected word line WL and selected bit lines BL/BLB (or the selected bit line BL for single-end read operation in a multi-port SRAM).

For purposes of description, FIG. 1B illustrates the schematic symbol for each word-line driver (WLDRV) 121 shown in FIG. 1A. For example, the word-line driver 121 has two input terminals I1 and I2, and an output terminal O1. The input terminals I1 and I2 are configured to receive an activation signal IN and an enable signal EN2, respectively. The output terminal O1 is coupled to a word line of memory cell, and is configured to provide an output signal OUT to the word line. Each word-line driver 121 is supplied with the power supply voltage V_{DD} and a reference voltage V_{SS}. In some embodiments, the activation signal IN of each word-line driver 121 may be generated from the corresponding decoded row address signal ADDR_Y, while the enable signal EN2 may refer to the write enable signal WE received by the memory controller 110. Additionally, the output signal OUT generated by the activated word-line driver 121 (e.g., with the activation signal IN being asserted, which could be “1” or “0”, depending on the circuit design) may be the word-line assertion signal for the corresponding word line (e.g., one of word lines WL1 to WLn) within the memory array 130.

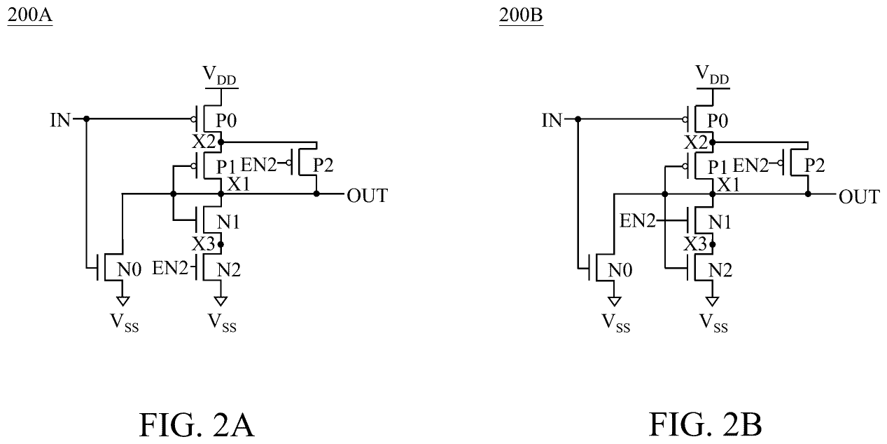

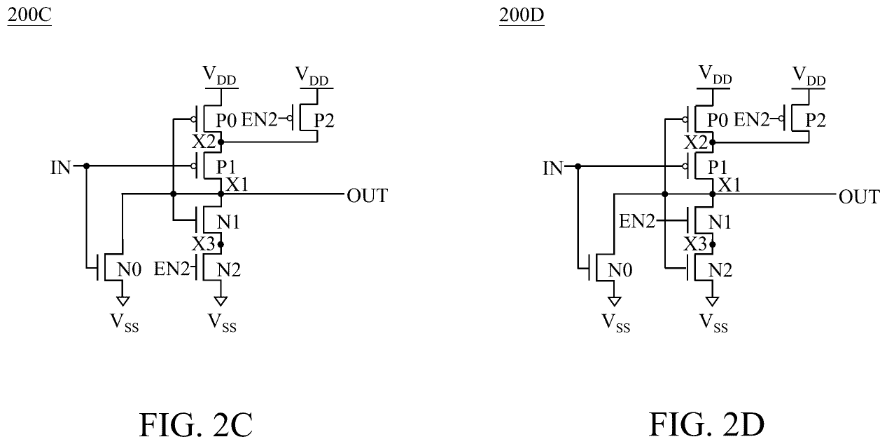

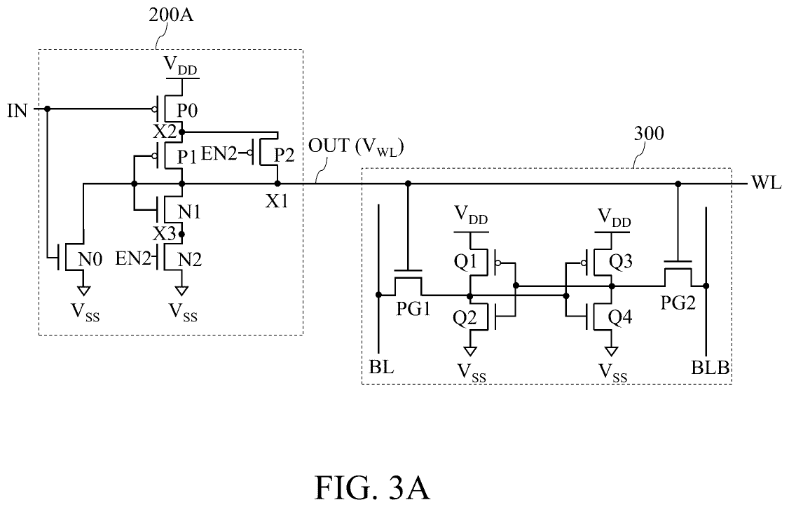

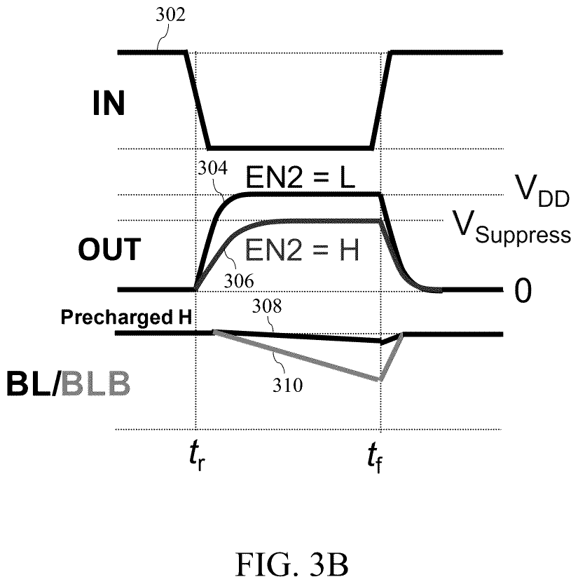

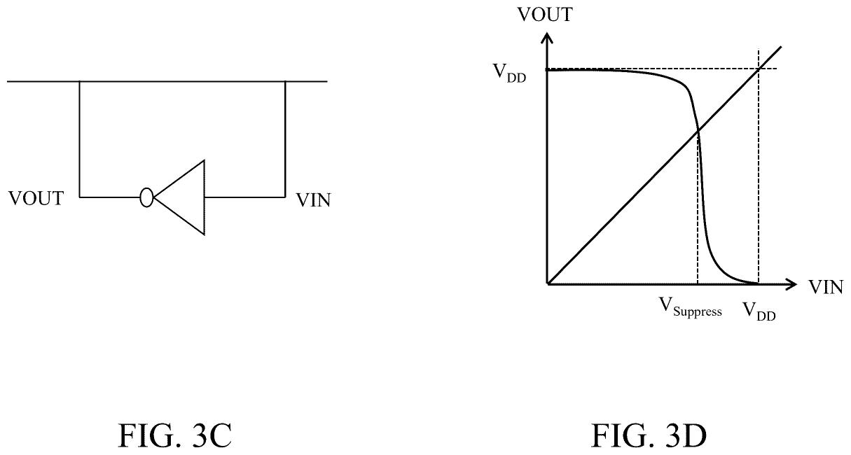

FIGS. 2A to 2D are schematic diagrams of a word-line driver in accordance with some embodiments of the present disclosure. FIG. 3A is a schematic diagram of a word-line driver coupled to a memory cell in accordance with the embodiment of FIG. 2A. FIG. 3B is a waveform diagram of various signals in FIG. 3A.

In some embodiments, the word-line driver 121 shown in FIG. 1B can be implemented using one of the word-line drivers 200A to 200D for use by an active-high word line of a memory cell, as shown in FIGS. 2A to 2D. Referring to FIG. 2A, the word-line driver 200A includes transistors N0 to N2 and P0 to P2, where transistors N0 to N2 are N-type transistors, and transistors P0 to P2 are P-type transistors. Transistor N0, which is a voltage pull-down device, includes a gate terminal receiving the input signal IN, a first drain/source terminal coupled to node X1, a second drain/source terminal receiving the reference voltage V_{SS}. Transistor N1 includes a gate terminal coupled to node X1, a first drain/source terminal coupled to node X1, and a second drain/source terminal coupled to node X3, while transistor N2 includes a gate terminal receiving the enable signal EN2, a first drain/source terminal coupled to node X3, and a second drain/source terminal receiving the reference voltage V_{SS}. Transistor P0, which is a voltage pull-up device, includes a gate terminal receiving the input signal IN, a first drain/source terminal receiving the power supply voltage V_{DD}, a second drain/source terminal coupled to node X2, while transistor P1 includes a gate terminal coupled to node X1, a first drain/source terminal coupled to node X2, a second drain/source terminal coupled to node X1. Transistor P2 includes a gate terminal receiving the enable signal EN2, a first drain/source terminal coupled to node X2, a second drain/source terminal coupled to node X1.

In some embodiments, transistors P0 and N0, with their gate terminals receiving the activation signal IN, can be collectively regarded as an input stage of the word-line driver 200A. Additionally, transistors P1 and N1, which forms an inverter, can be collectively regarded as a driving stage for WLUD of the word-line driver 200A. In some embodiments, when the enable signal EN2 is in the high logic state (e.g., “1”), transistors P1 and N1 drive the corresponding word line. When the enable signal EN2 is in the low-logic state (e.g., “0”), transistors P0, P2, and N0 drive the corresponding word line. Furthermore, transistors P2 and N2, with their gate terminals receiving the enable signal EN2, can be regarded as a supplementary voltage pull-up device and a switch device of the word-line driver 200A, respectively.

In some embodiments, node X1 refers to an output terminal of the word-line driver 200A, which is coupled to an associated word line within the memory cell 300 (e.g., a 6-transistor SRAM cell, but the disclosure is not limited thereto) with an active-high word line, as shown in FIG. 3A. Additionally, the enable signal EN2 is a low-active write enable signal, indicating that the high logic state (e.g., “1”) and low logic state (e.g., “0”) of the enable signal EN2 are for the read operation and the write operation, respectively. When the enable signal EN2 is in the high logic state (e.g., “1”), the output signal OUT swings between the reference voltage V_{SS} (e.g., ground voltage of 0V) and a suppression voltage V_{Suppress} (e.g., lower than V_{DD}). At this time, the word-line driver 200A can be used for a read operation using the word-line under drive (WLUD) technique to suppress the voltage level of the asserted word line within the memory array 130, thereby enhancing static noise margin and reducing power consumption during the read operation. When the enable signal EN2 is in the low logic state (e.g., “0”), the output signal OUT swings between the reference voltage V_{SS} and the power supply voltage V_{DD}. At this time, the word-line driver 200A can be used for a write operation without the WLUD technique. It should be noted that the suppression voltage Vₛᵤₚₚᵣₑₛₛ is higher than the threshold voltage V_{TH} of the pass gates PG1 and PG2 (e.g., N-type transistors) of the memory cell 300 coupled to the word-line driver 200A, as shown in FIG. 3A, thereby turning on the pass gates PG1 and PG2 when the output signal OUT is in the high logic state (e.g., V_{DD} for the write operation, or V_{Suppress} for the read operation). Additionally, the suppression voltage V_{Suppress} can be tuned by adjusting the transistor sizes and/or threshold voltages of transistors P1 and N1, the details of which will be described later.

The detailed operations of the word-line driver 200A are described with references to FIGS. 3A and 3B as follows. In some embodiments, each memory cell 131 shown in FIG. 1A can be implemented using the memory cell 300 shown in FIG. 3A. Additionally, the output terminal of the word-line driver 200A is coupled to the word line WL of the memory cell 300. For purposes of description, the output signal OUT generated by the word-line driver 200A may also be referred to as the word line assertion signal for the word line WL of the memory cell 300.

In the first scenario, the enable signal EN2 is in the high logic state (“1”, “H’, or V_{DD}), indicating a read operation is performed on the memory cell 300. Additionally, transistor P2 is turned off, and transistor N2 is turned on. It should be noted that the precharge circuit 141 may precharge the voltage level of the bit line pair BL and BLB to the high logic state (e.g., “1” or V_{DD}) prior to the read operation, as shown by curves 308 and 310 in FIG. 3B. Initially, when the activation signal IN, as shown by curve 302 in FIG. 3B, is in the high logic state, transistor P0 is turned off, and transistor N0 is turned on. Accordingly, the voltage level of the output signal OUT (i.e., V_{WL}) at node X1, as shown by curve 306 in FIG. 3B, is pulled down to the reference voltage V_{SS} (e.g., 0V) through transistor N0, turning off transistor N1 and turning on transistor P1. At time tᵣ, the activation signal IN switches from the high logic state (e.g., V_{DD}) to the low logic state (e.g., V_{SS} or ground), turning on transistor P0 and turning off transistor N0. At this time, the voltage level of the output signal OUT (i.e., V_{WL}), as shown by curve 306 in FIG. 3B, is pulled up through transistors P0 and P1. When the voltage level of the output signal OUT (i.e., V_{WL}) increases to the threshold voltage V_{TH} of transistor N1, transistor N1 is turned on, indicating that the voltage pull-down path through transistors N1 and N2 is activated, and a race condition between voltage pull-down and voltage pull-up could occur.

In this situation, the word-line driver 200A is equivalent to an inverter with its input terminal and output terminal shorted, as shown by FIG. 3C, and the suppression voltage V_{Suppress} is determined according to the ratio of the driving capabilities of transistors P0 and P1 to those of transistors N1 and N2. This indicates that the voltage level of the suppression voltage V_{Suppress} can be controlled by varying the driving capabilities of transistors P0, P1, N1, and N2, such as changing their transistor sizes (e.g., W/L ratio for planar FETs, the number of fingers for finFETs, or number of sheets for nanosheet FETs) and/or threshold voltages. In some implementations, when the driving capabilities of transistors P0 and P1 are greater than those of transistors N1 and N2, the voltage level of the suppression voltage V_{Suppress} is higher than V_{DD}/2 for the word-line driver 200A, as shown in FIG. 3D. It should be noted that the suppression voltage V_{Suppress} is higher than the threshold voltage V_{THn} (e.g., a positive voltage) of the pass gates PG1 and PG2 (e.g., N-type transistors) of the memory cell 300 coupled to the word-line driver 200A, as shown in FIG. 3A, thereby turning on the pass gates PG1 and PG2 when the output signal OUT is in the high logic state (e.g., “1”, such as V_{DD} or V_{Suppress}).

Referring back to FIG. 3B, at time t_{f}, the activation signal IN switches from the low logic state (e.g., “0” or V_{SS}) to the high logic state (e.g., “1” or V_{DD}), turning off transistor P0 and turning on transistor N0. Accordingly, the voltage level of the output signal OUT (i.e., V_{WL}) is pulled down from the suppression voltage V_{Suppress} to the ground (e.g., 0V or V_{SS}) through transistor N0.

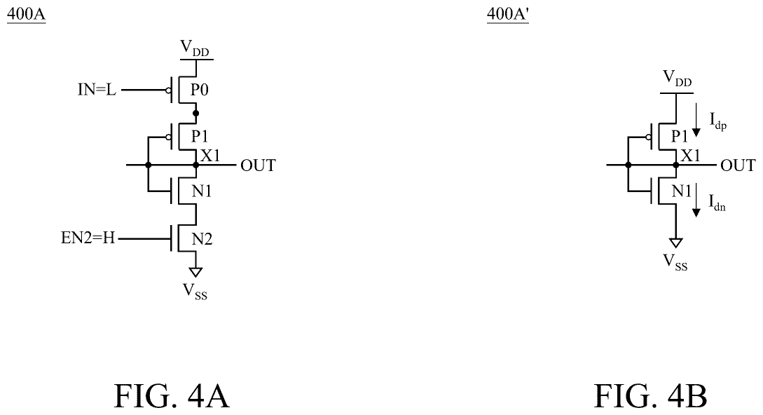

In some embodiments, when the enable signal EN2 and the activation signal IN are in the high logic state and the low logic state, respectively, the equivalent circuit of the word-line driver 200A is shown by circuit 400A in FIG. 4A. Since transistors P0 and N2 are turned on, circuit 400A in FIG. 4A can be simplified to circuit 400A′ as shown in FIG. 4B.

At this time, since the gate-to-source voltage V_{GS} of transistor P1 equals the drain-to-source voltage V_{DS}, which approximately equals V_{OUT}−V_{DD}, transistor P1 enters the saturation region. Additionally, since the gate-to-source voltage V_{GS} of transistor N1 equals the drain-to-source voltage V_{DS}, which approximately equals V_{OUT}, transistor N1 enters the saturation region. This indicates that the saturation current flowing I_{dp} through transistor P1 is equal to the saturation current Ian flowing through transistor N1. For brevity, let transconductance parameters

$${k}_{n} = {μ}_{n} {C}_{o x n} \frac{{W}_{n}}{{L}_{n}}$$

and coefficient

$${k}_{p} = {μ}_{p} {C}_{o x p} \frac{{W}_{p}}{{L}_{p}} ,$$

the saturation current Ian of transistor N1 can be expressed can be expressed as

$${I}_{d n} = \frac{1}{2} {{k}_{n} ( {V}_{S u p p r e s s} - {V}_{T H n} )}^{2} ,$$

wile the saturation current I_{dp} of transistor P1 can be expressed as

$${I}_{d p} = \frac{1}{2} {{k}_{p} ( {V}_{D D} - {V}_{S u p p r e s s} - {V}_{T H p} )}^{2} .$$

Here, Wₚ and Lₚ denote the channel width and channel length of transistor P1, respectively; up denotes the mobility of PMOS holes; Cₒₓₚ denotes the gate oxide capacitance of transistor P1; and V_{THp} denotes the threshold voltage of transistor P1. Additionally, Ln and Wₙ denote the channel length and channel width of transistor N1, respectively; Un denotes the mobility of NMOS electrons; Cₒₓₙ denotes the gate oxide capacitance of transistor N1; and V_{THn} denotes the threshold voltage of transistor N1. Specifically, when the voltage level of the output signal OUT reaches the suppression voltage V_{Suppress}, the saturation current I_{dn} of transistor N1 equals the saturation current I_{dp} of transistor P1. Accordingly, the suppression voltage V_{Suppress} can be expressed using equation (1) as follows.

$${V}_{S u p p e s s} = \frac{\sqrt{{k}_{p}} {V}_{D D} - \sqrt{{k}_{p}} {V}_{T H p} + \sqrt{{k}_{n}} {V}_{T H n}}{\sqrt{{k}_{p}} + \sqrt{{k}_{n}}} = \frac{1 - \frac{{V}_{T H p}}{{V}_{D D}} + \sqrt{{k}_{r}} \frac{{V}_{T H n}}{{V}_{D D}}}{1 + \sqrt{{k}_{r}}} {V}_{D D} \qquad ( 1 )$$

In formula (1), the transconductance-parameter ratio

$${k}_{r} = \frac{{k}_{n}}{{k}_{p}} .$$

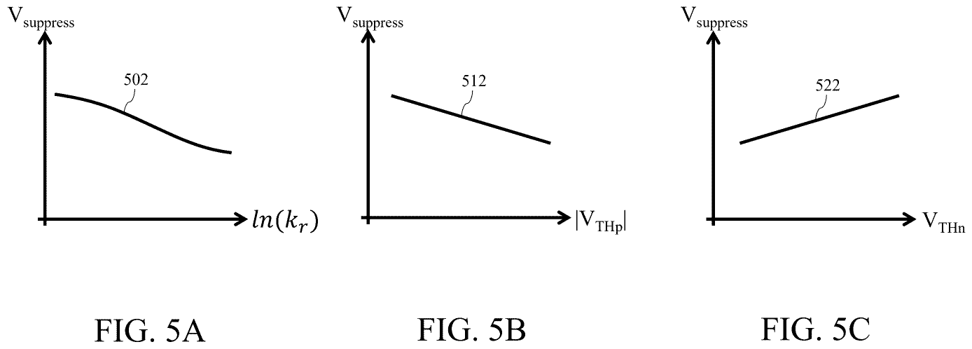

In other words, the suppression voltage V_{Suppress} can be adjusted by changing any of the aforementioned parameters of transistors P1 and N1. For example, when the channel width Wₙ of transistor N1 is reduced, the transconductance parameter kₙ decreases, and the transconductance-parameter ratio kᵣ of the also decreases, resulting in an increase of the suppression voltage V_{Suppress} because the threshold voltage V_{THn}<V_{DD}. Alternatively, when the threshold voltage V_{THn} of transistor N1 increases, the suppression voltage V_{Suppress} also increases. In other words, the decrease of the driving capability of transistor N1, such as channel width Wₙ and/or threshold voltage V_{THn}, results in an increase of the suppression voltage V_{Suppress}. Additionally, the suppression voltage V_{Suppress} can be tuned by adjusting the channel width Wₚ and threshold voltage V_{THp} of transistor P1 according to formula (1) in a similar fashion. In brief, the suppression voltage V_{Suppress} decreases as the value of ln(kᵣ) and the threshold voltage |V_{THp}| increases, as shown by curves 502 and 512 in FIGS. 5A and 5B. Furthermore, the suppression voltage V_{Suppress} increases as the threshold voltage V_{THn} increases, as shown by curve 522 in FIG. 5C.

In the second scenario, the enable signal EN2 is in the low logic state (“0”, “L”, or V_{SS}/GND), indicating a write operation is performed on the memory cell 300. Additionally, transistor P2 is turned on, and transistor N2 is turned off. It should be noted that the precharge circuit 141 may precharge the voltage level of the bit line pair BL and BLB to the high logic state (e.g., “1”, “H”, or V_{DD}) prior to the write operation, as shown by curves 308 and 310 in FIG. 3B. Initially, when the activation signal IN is in the high logic state, transistor P0 is turned off, and transistor N0 is turned on. Accordingly, the voltage level of the output signal OUT (i.e., V_{WL}) at node X1, as shown by curve 304 in FIG. 3B, is pulled down to the reference voltage V_{SS} (or the ground) through transistor N0, turning off transistor N1 and turning on transistor P1. At time tᵣ, the activation signal IN switches from the high logic state (e.g., V_{DD}) to the low logic state (e.g., V_{SS} or ground), turning on transistor P0 and turning off transistor N0. At this time, the voltage level of the output signal OUT (i.e., V_{WL}), as shown by curve 304 in FIG. 3B, is pulled up toward the power supply voltage V_{DD} through transistors P0, P1, and P2. It should be noted that transistor P1 is turned on until the voltage level of the output signal OUT (i.e., V_{WL}) reaches V_{DD}−|V_{THp}|. However, the voltage level of the output signal OUT (i.e., V_{WL}) can be pulled up to the power supply voltage V_{DD} through transistor P2 and P0 when transistor P1 is turned off. At time t_{f}, the activation signal IN switches from the low logic state (e.g., V_{SS} or ground) to the high logic state (e.g., V_{DD}), turning off transistor P0 and turning on transistor N0. Accordingly, the voltage level of the output signal OUT (i.e., V_{WL}) is pulled down from the power supply voltage V_{DD} to the ground (e.g., 0V or V_{SS}) through transistor N0.

Specifically, when the word-line driver 200A is used for a read operation (e.g., EN2=“1”), the output signal OUT swings within a first voltage domain, such as swinging between the reference voltage V_{SS} (e.g., 0V) and the suppression voltage V_{Suppress} (e.g., lower than V_{DD}), using the word-line under drive (WLUD) technique (e.g., a read-assist technique), thereby suppressing the word-line voltage of the asserted word line during the read operation to maintain the static noise margin. When the word-line driver 200A is used for a write operation (e.g., EN2=“0”), the output signal OUT swings within a second voltage domain, such as swinging between the reference voltage V_{SS} and the power supply voltage V_{DD}, without the WLUD technique during the write operation. Additionally, the second voltage domain for the write operation is wider than the first voltage domain for the read operation.

In some embodiments, the word-line drivers 200B to 200D shown in FIGS. 2B to 2D are similar to the word-line driver 200A shown in FIG. 2A, which includes an input stage, a driving stage, supplementary voltage pull-up and pull-down devices, but with different electrical connections of the activation signal IN and the enable signal EN2. For example, the word-line driver 200B shown in FIG. 2B differs from the word-line driver 200A in that the enable signal EN2 is provided to the gate terminal of transistor N1, and the gate terminals of transistors N2 and P1 are coupled to node X1, as shown in FIG. 2B. The operations of the word-line driver 200B shown in FIG. 2B are similar to those of the word-line driver 200A shown in FIG. 2A, the details of which are not repeated here. Additionally, the suppression voltage V_{Suppress} used by the word-line driver 200B can be tuned by adjusting the transistor sizes and/or threshold voltages of transistors P1 and N2 in a manner similar to the embodiment of FIG. 2A. In some embodiments, transistors P0 and N0, with their gate terminals receiving the activation signal IN, can be collectively regarded as the input stage of the word-line driver 200B, while transistors P1 and N2, which forms an inverter, can be collectively regarded as a driving stage of the word-line driver 200B. Additionally, transistors P2 and N1, with their gate terminals receiving the enable signal EN2, can be regarded as a supplementary voltage pull-up device and a switch device of the word-line driver 200B, respectively.

Additionally, the word-line driver 200C shown in FIG. 2C differs from the word-line driver 200A in that the activation signal IN is provided to the gate terminals of transistors N0 and P1, the gate terminals of transistors N1 and P0 are coupled to node X1, and transistor P2 is coupled between the power supply voltage V_{DD} and node X2, as shown in FIG. 2C. The operations of the word-line driver 200C shown in FIG. 2C are similar to those of the word-line driver 200A shown in FIG. 2A, the details of which are not repeated here. Additionally, the suppression voltage V_{Suppress} used by the word-line driver 200C can be tuned by adjusting the transistor sizes and/or threshold voltages of transistors P0 and N1 in a manner similar to the embodiment of FIG. 2A. In some embodiments, transistors P1 and N0, with their gate terminals receiving the activation signal IN, can be collectively regarded as the input stage of the word-line driver 200C, while transistors P0 and N1, which forms an inverter, can be collectively regarded as a driving stage of the word-line driver 200C. Additionally, transistors P2 and N2, with their gate terminals receiving the enable signal EN2, can be regarded as a supplementary voltage pull-up device and a switch device of the word-line driver 200C, respectively.

Furthermore, the word-line driver 200D shown in FIG. 2D differs from the word-line driver 200A in that the activation signal IN is provided to the gate terminals of transistors N0 and P1, the enable signal EN2 is provided to the gate terminal of transistor N1, the gate terminals of transistors N2 and P0 are coupled to node X1, and transistor P2 is coupled between the power supply voltage V_{DD} and node X2, as shown in FIG. 2D. The operations of the word-line driver 200D shown in FIG. 2D are similar to those of the word-line driver 200A shown in FIG. 2A, the details of which are not repeated here. Additionally, the suppression voltage V_{Suppress} used by the word-line driver 200D can be tuned by adjusting the transistor sizes and/or threshold voltages of transistors P0 and N2 in a manner similar to the embodiment of FIG. 2A. In some embodiments, transistors P1 and N0, with their gate terminals receiving the activation signal IN, can be collectively regarded as the input stage of the word-line driver 200D, while transistors P0 and N2, which forms an inverter, can be collectively regarded as a driving stage of the word-line driver 200D. Additionally, transistors P2 and N1, with their gate terminals receiving the enable signal EN2, can be regarded as a supplementary pull-up device and a switch device of the word-line driver 200D, respectively.

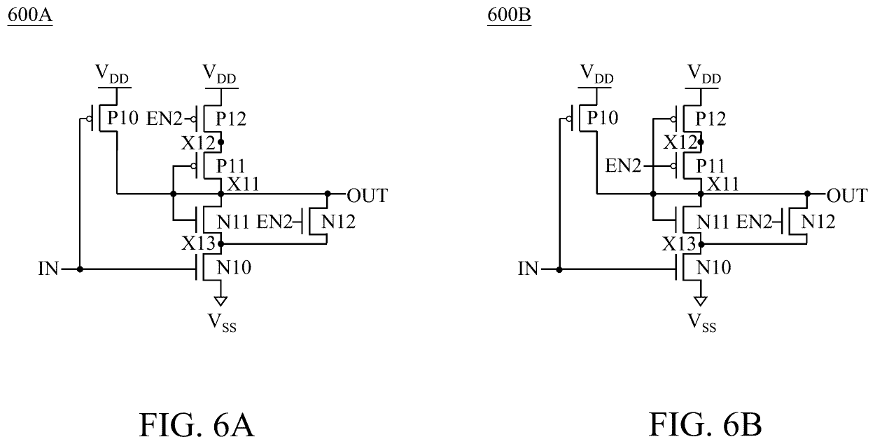

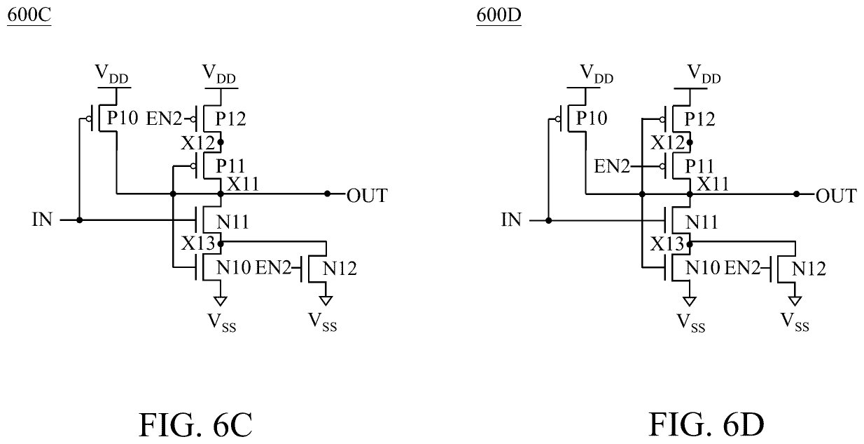

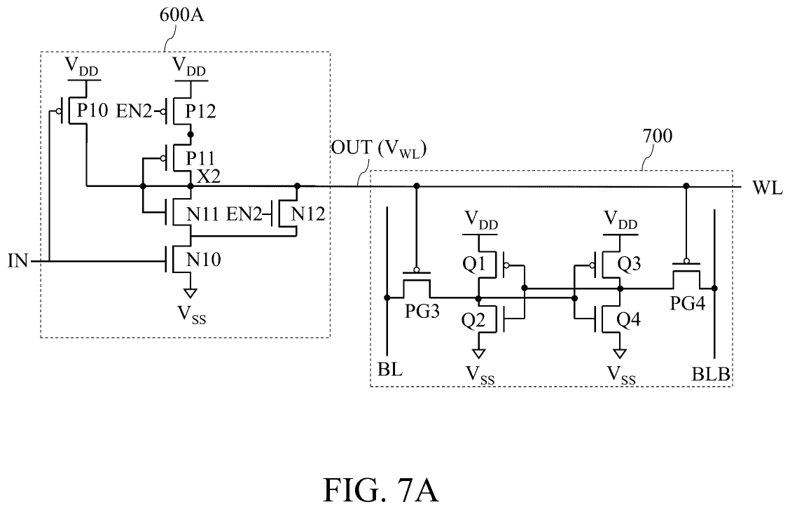

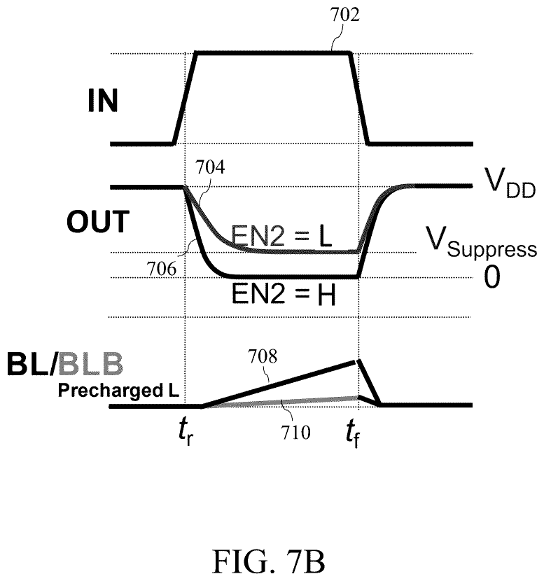

FIGS. 6A to 6D are schematic diagrams of a word-line driver in accordance with still some embodiments of the present disclosure. FIG. 7A is a schematic diagram of a word-line driver coupled to a memory cell in accordance with the embodiment of FIG. 6A. FIG. 7B is a waveform diagram of various signals in FIG. 7A.

In some embodiments, the word-line driver 121 shown in FIG. 1B can be implemented using one of the word-line drivers 600A to 600D for use by an active-low word line of a memory cell, as shown in FIGS. 6A to 6D. Referring to FIG. 6A, the word-line driver 600A includes transistors N10 to N12 and P10 to P12, where transistors N10 to N12 are N-type transistors and transistors P10 to P12 are P-type transistors. Transistor N10, which is a voltage pull-down device, includes a gate terminal receiving the activation signal IN, a first drain/source terminal coupled to node X13, a second drain/source terminal receiving the reference voltage V_{SS}. Transistor N11 includes a gate terminal coupled to node X11, a first drain/source terminal coupled to node X11, and a second drain/source terminal coupled to node X13, while transistor N12 includes a gate terminal receiving the enable signal EN2, a first drain/source terminal coupled to node X11, and a second drain/source terminal coupled to node X13. Transistor P10, which is a voltage pull-up device, includes a gate terminal receiving the input signal IN, a first drain/source terminal receiving the power supply voltage V_{DD}, a second drain/source terminal coupled to node X11. Transistor P11 includes a gate terminal coupled to node X11, a first drain/source terminal coupled to node X12, a second drain/source terminal coupled to node X11, while transistor P12 includes a gate terminal receiving the enable signal EN2, a first drain/source terminal receiving the power supply voltage V_{DD}, a second drain/source terminal coupled to node X12.

In some embodiments, transistors P10 and N10, with the gate terminals receiving the activation signal IN, can be collectively regarded as an input stage of the word-line driver 600A. Additionally, transistors P11 and N11, which forms an inverter, can be collectively regarded as a driving stage of the word-line driver 600A. Furthermore, transistors P12 and N12, with their gate terminals receiving the enable signal EN2, can be regarded as a switch device and a supplementary voltage pull-down device of the word-line driver 600A, respectively.

In some embodiments, node X11 refers to an output terminal of the word-line driver 600A, which is coupled to an associated active-low word line WL within the memory cell 700 (e.g., a 6-transistor SRAM cell, but the disclosure is not limited thereto), as shown in FIG. 7A. Additionally, the enable signal EN2 is a high-active write enable signal, indicating that the high logic state (e.g., “1”) and low logic state (e.g., “0”) of the enable signal EN2 are for the write operation and read operation, respectively. When the enable signal EN2 is in the low logic state (e.g., “0”), the output signal OUT swings between the power supply voltage V_{DD} and the suppression voltage V_{Suppress} (e.g., >0V). At this time, the word-line driver 600A can be used for a read operation using the word-line under drive (WLUD) technique. When the enable signal EN2 is in the high logic state (e.g., “1”), the output signal OUT swings between the power supply voltage V_{DD} and the reference voltage V_{SS} (e.g., ground voltage of 0V). At this time, the word-line driver 600A can be used for a write operation without the WLUD technique. It should be noted that the suppression voltage V_{Suppress} is a positive voltage lower than the power supply voltage V_{DD}, and the difference between the power supply voltage V_{DD} and the suppression voltage V_{Suppress} (e.g., V_{DD}−V_{Suppress}) is greater than the threshold voltage |V_{THp}| of the pass gates PG3 and PG4 (e.g., P-type transistors) of the memory cell 700 coupled to the word-line driver 600A, as shown in FIG. 7A, thereby turning on the pass gates PG3 and PG4 when the output signal OUT is in the low logic state (e.g., 0V for the write operation, or V_{Suppress} for the read operation). Additionally, the suppression voltage V_{Suppress} can be tuned by adjusting the sizes and/or threshold voltages of transistors P11 and N11.

The detailed operations of the word-line driver 600A are described with references to FIGS. 7A and 7B as follows. In some embodiments, each memory cell 131 shown in FIG. 1A can be implemented using the memory cell 700 shown in FIG. 7A. Additionally, the output terminal of the word-line driver 600A is coupled to the word line WL of the memory cell 700. For purposes of description, the output signal OUT generated by the word-line driver 600A may also be referred to as the word line assertion signal for the word line WL of the memory cell 700.

In the first scenario, the enable signal EN2 is in the low logic state (“0” or V_{SS}), indicating a read operation is performed on the memory cell 700. Additionally, transistor P12 is turned on, and transistor N12 is turned off. It should be noted that the precharge circuit 141 may precharge the voltage level of the bit line pair BL and BLB to the low logic state (e.g., “0” or V_{SS}) prior to the read operation, as shown by curves 708 and 710 in FIG. 7B. Initially, when the activation signal IN, as shown by curve 702 in FIG. 7B, is in the low logic state, transistor P10 is turned on, and transistor N10 is turned off. Accordingly, the voltage level of the output signal OUT (i.e., V_{WL}) at node X11, as shown by curve 704 in FIG. 7B, is pulled up to the power supply voltage V_{DD} through transistor P10, turning off transistor P11 and turning on transistor N11. At time tᵣ, the activation signal IN switches from the low logic state (e.g., “0” or V_{SS}/GND) to the high logic state (e.g., “1” or V_{DD}), turning on transistor N10 and turning off transistor P10. At this time, the voltage level of the output signal OUT (i.e., V_{WL}), as shown by curve 704 in FIG. 7B, is pulled down through transistors N12 and N10. When the voltage level of the output signal OUT (i.e., V_{WL}) decreases to the V_{DD}−|V_{THp}| (e.g., V_{THp} refers to the threshold voltage of transistor P11, which is a negative voltage), transistor P11 is turned on, indicating that the voltage pull-up path through transistors P11 and P12 is activated, and a race condition between voltage pull-down and voltage pull-up could occur.

In the race condition, the suppression voltage V_{Suppress} can be determined according to the ratio of the driving capabilities of transistors P11 and P12 to those of transistors N10 and N11 in a manner similar to the embodiment of FIGS. 3C to 3D. This indicates that the voltage level of the suppression voltage V_{Suppress} can be controlled by varying the driving capabilities of transistors P11, P12, N10, and N11, such as changing their transistor sizes (e.g., W/L ratio for planar FETs, the number of fingers for finFETs, or number of sheets for nanosheet FETs) or threshold voltages. In some implementations, when the driving capabilities of transistors N10 and N11 are greater than those of transistors P11 and P12, the voltage level of the suppression voltage V_{Suppress} is lower than V_{DD}/2 for the word-line driver 600A. It should be noted that the difference between the suppression voltage V_{Suppress} and the power supply voltage V_{DD} (i.e., V_{Suppress}−V_{DD}) is lower than the threshold voltage V_{THp} (e.g., a negative voltage) of the pass gates PG3 and PG4 (e.g., P-type transistors) of the memory cell 700 coupled to the word-line driver 600A, as shown in FIG. 7A, thereby turning on the pass gates PG3 and PG4 when the output signal OUT is in the low logic state (e.g., “0” or V_{Suppress}).

Referring back to FIG. 7B, at time t_{f}, the activation signal IN switches from the high logic state (e.g., “1” or V_{DD}) to the low logic state (e.g., “0” or V_{SS}), turning on transistor P10 and turning off transistor N10. Accordingly, the voltage level of the output signal OUT (i.e., V_{WL}) is pulled up from the suppression voltage V_{Suppress} to the power supply voltage V_{DD} through transistor P10.

In the second scenario, the enable signal EN2 is in the high logic state (“1”, “H”, or V_{DD}), indicating a write operation is performed on the memory cell 700. Additionally, transistor P12 is turned off, and transistor N12 is turned on. It should be noted that the precharge circuit 141 may precharge the voltage level of the bit line pair BL and BLB to the low logic state (e.g., “0”, “L”, or V_{SS}) prior to the write operation, as shown by curves 708 and 710 in FIG. 7B. Initially, when the activation signal IN is in the low logic state, transistor P10 is turned on, and transistor N10 is turned off. Accordingly, the voltage level of the output signal OUT (i.e., V_{WL}) at node X11, as shown by curve 706 in FIG. 7B, is pulled up to the power supply voltage V_{DD} through transistor P10, turning off transistor P11 and turning on transistor N11. At time tᵣ, the activation signal IN switches from the low logic state (e.g., V_{SS} or ground) to the high logic state (e.g., V_{DD}), turning off transistor P10 and turning on transistor N10. At this time, the voltage level of the output signal OUT (i.e., V_{WL}), as shown by curve 706 in FIG. 3B, is pulled down to the reference voltage V_{SS} (e.g., 0V) through transistors N10, N11, and N12. It should be noted that transistor N11 is turned on until the voltage level of the output signal OUT (i.e., V_{WL}) reaches the threshold voltage V_{THn} of transistor N11. However, the voltage level of the output signal OUT (i.e., V_{WL}) can be pulled down to the reference voltage (e.g., 0V) through transistor N12 and N10 even when transistor N11 is turned off. At time t_{f}, the activation signal IN switches from the high logic state (e.g., V_{DD}) to the low logic state (e.g., V_{SS} or ground), turning on transistor P10 and turning off transistor N10. Accordingly, the voltage level of the output signal OUT (i.e., V_{WL}) is pulled up from the reference voltage V_{SS} (e.g., 0V) to the power supply voltage V_{DD} through transistor P10.

Specifically, when the word-line driver 600A is used for a read operation (e.g., EN2=“0”), the output signal OUT swings within a first voltage domain, such as swinging between the power supply voltage V_{DD} and the suppression voltage V_{Suppress} (e.g., lower than V_{DD}), using the word-line under drive (WLUD) technique (e.g., a read-assist technique), thereby suppressing the word-line voltage of the selected word line to maintain the static noise margin. When the word-line driver 600A is used for a write operation (e.g., EN2=“1”), the output signal OUT swings within a second voltage domain, such as swinging between the power supply voltage V_{DD} and the reference voltage V_{SS} (e.g., 0V), without the WLUD technique. Additionally, the second voltage domain for the write operation is wider than the first voltage domain for the read operation.

In some embodiments, the word-line drivers 600B to 600D shown in FIGS. 6B to 6D are similar to the word-line driver 600A shown in FIG. 6A, but with different electrical connections of the activation signal IN and the enable signal EN2. For example, the word-line driver 600B shown in FIG. 6B differs from the word-line driver 600A in that the enable signal EN2 is provided to the gate terminal of transistor P11, and the gate terminals of transistors N11 and P12 are coupled to node X11, as shown in FIG. 6B. The operations of the word-line driver 600B shown in FIG. 6B are similar to those of the word-line driver 600A shown in FIG. 6A, the details of which are not repeated here. Additionally, the suppression voltage V_{Suppress} used by the word-line driver 600B can be tuned by adjusting the sizes and/or threshold voltages of transistors P12 and N11 in a manner similar to the embodiment of FIG. 6A. In some embodiments, transistors P10 and N10, with the gate terminals receiving the activation signal IN, can be collectively regarded as an input stage of the word-line driver 600B. Additionally, transistors P12 and N11, which forms an inverter, can be collectively regarded as a driving stage of the word-line driver 600B. Furthermore, transistors P11 and N12, with their gate terminals receiving the enable signal EN2, can be regarded as a switch device and a supplementary voltage pull-down device of the word-line driver 600B, respectively.

Additionally, the word-line driver 600C shown in FIG. 6C differs from the word-line driver 600A in that the activation signal IN is provided to the gate terminals of transistors N11 and P10, the gate terminals of transistors N10 and P11 are coupled to node X11, and transistor N12 is coupled between node X11 and the reference voltage V_{SS}, as shown in FIG. 6C. The operations of the word-line driver 600C shown in FIG. 6C are similar to those of the word-line driver 600A shown in FIG. 6A, the details of which are not repeated here. Additionally, the suppression voltage V_{Suppress} used by the word-line driver 600C can be tuned by adjusting the sizes and/or threshold voltages of transistors P11 and N10 in a manner similar to the embodiment of FIG. 6A. In some embodiments, transistors P10 and N11, with the gate terminals receiving the activation signal IN, can be collectively regarded as an input stage of the word-line driver 600C. Additionally, transistors P11 and N10, which forms an inverter, can be collectively regarded as a driving stage of the word-line driver 600C. Furthermore, transistors P12 and N12, with their gate terminals receiving the enable signal EN2, can be regarded as a switch device and a supplementary voltage pull-down device of the word-line driver 600C, respectively.

Furthermore, the word-line driver 600D shown in FIG. 6D differs from the word-line driver 600A in that the activation signal IN is provided to the gate terminals of transistor N11 and P10, the enable signal EN2 is provided to the gate terminal of transistor P11, the gate terminals of transistors N10 and P12 are coupled to node X11, and transistor N12 is coupled between node X11 and the reference voltage V_{SS}, as shown in FIG. 6D. The operations of the word-line driver 600D shown in FIG. 6D are similar to those of the word-line driver 600A shown in FIG. 6A, the details of which are not repeated here. Additionally, the suppression voltage V_{Suppress} used by the word-line driver 600D can be tuned by adjusting the sizes and/or threshold voltages of transistors P12 and N10 in a manner similar to the embodiment of FIG. 6A. In some embodiments, transistors P10 and N11, with the gate terminals receiving the activation signal IN, can be collectively regarded as an input stage of the word-line driver 600D. Additionally, transistors P12 and N10, which forms an inverter, can be collectively regarded as a driving stage of the word-line driver 600D. Furthermore, transistors P11 and N12, with their gate terminals receiving the enable signal EN2, can be regarded as a switch device and a supplementary voltage pull-down device of the word-line driver 600D, respectively.

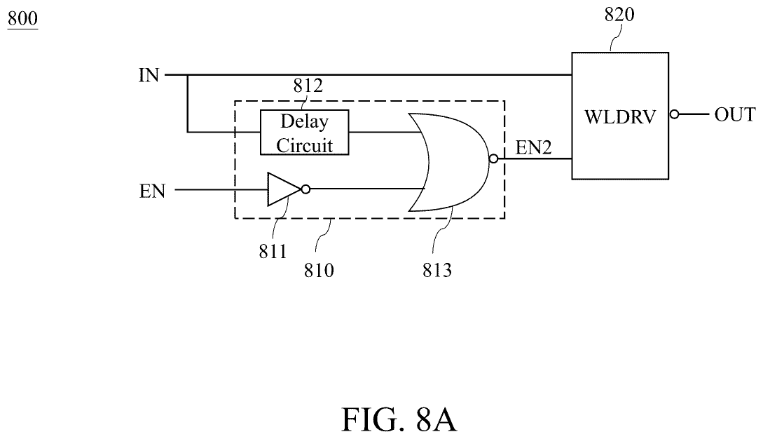

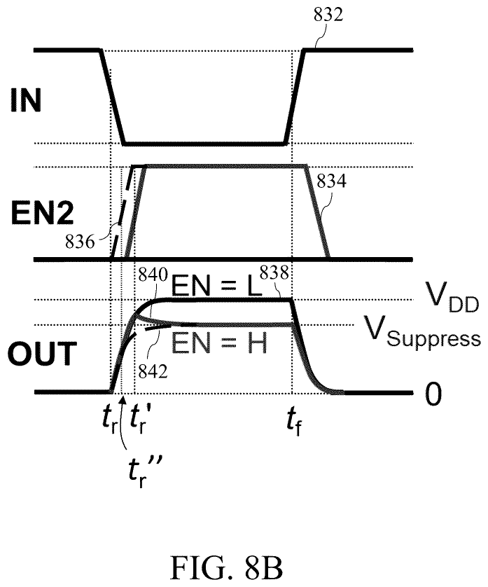

FIG. 8A is a block diagram of a word-line driver in accordance with still some embodiments of the present disclosure. FIG. 8B is a waveform diagram of various signals within the word-line driver in FIG. 8A.

In some embodiments, the word-line driver 121 shown in FIG. 1B can be implemented using the word-line driver 800 for use by an active-high word line of a memory cell, as shown in FIG. 8A. The word-line driver 800 includes a control circuit 810 and a word-line driver 820. The word-line driver 820 could be any of the word-line drivers 200A to 200D shown in FIGS. 2A to 2D. The control circuit 810 is configured to provide a sharper rise transition for the output signal OUT generated by the word-line driver 820. As shown in FIG. 8A, the control circuit 810 includes an inverter 811, a delay circuit 812, and a NOR gate 813. The delay circuit 812 may be implemented using an inverter chain, one or more buffers, or any other logically equivalent circuits. Additionally, the control circuit 810 can be implemented using any other logically equivalent circuits.

For example, when the enable signal EN is in the high logic state (e.g., “1”), it indicates that the word-line driver 800 is used for a read operation. The activation signal IN, as shown by curve 832 in FIG. 8B, switches from the high logic state (“1”) to the low logic state (“0”) at time tᵣ. For brevity, the delay time caused by the delay circuit 812 is tᵣ′−tᵣ (e.g., for the overshoot case of the output signal OUT) or tᵣ″−tᵣ (e.g., for the overdamped (or undershoot) case of the output signal OUT). Accordingly, the enable signal EN2, as shown by curve 834 or 836, generated by the NOR gate 813 is kept at the low logic state (e.g., “0”) until the delayed activation signal IN generated by the delay circuit 812 switches from the high logic state (“1”) to the low logic state (“0”) at time tᵣ′ for the overshoot case or at time tᵣ″ for the overdamped case, where time tᵣ″ is earlier than time tᵣ′.

Specifically, for the overshoot case of the output signal OUT, the delay circuit 812 can be designed to have a longer delay time, such as tᵣ′−tᵣ. This indicates that the enable signal EN2, as shown by curve 834 in FIG. 8B, received by the word-line driver 820 switches from the low logic state (e.g., “0”) to the high logic state (e.g., “1”) at time tᵣ′. Accordingly, the voltage level of the output signal OUT, as shown by curve 840 in FIG. 8B, is pulled up toward the power supply voltage V_{DD} during the time interval between times tᵣ and tᵣ′, and it may exceed the suppression voltage V_{Suppress} at time tᵣ′. At time tᵣ′, the voltage level of the output signal OUT is pulled down to and maintained at the suppression voltage V_{Suppress}.

For the overdamped case of the output signal OUT, the delay circuit 812 could be designed to have a shorter delay time, such as tᵣ″−tᵣ. This indicates that the enable signal EN2, as shown by curve 836 in FIG. 8B, received by the word-line driver 820 switches from the low logic state (e.g., “0”) to the high logic state (e.g., “1”) at time tᵣ″. Accordingly, the voltage level of the output signal OUT, as shown by curve 842 in FIG. 8B, is pulled up toward the power supply voltage V_{DD} during the time interval between times tᵣ and tᵣ″, and it does not exceed the suppression voltage V_{Suppress} at time tᵣ″. At time tᵣ″, the voltage level of the output signal OUT is pulled up to and maintained at the suppression voltage V_{Suppress}. It should be noted that the delay time caused by the delay circuit 812 can be appropriately designed, such that the voltage level of the output signal OUT is exactly pulled up to the suppression voltage V_{Suppress} at time tᵣ′, avoiding the overshoot and overdamped conditions.

When the enable signal EN is in the low logic state (e.g., “0”), it indicates that the word-line driver 800 is used for a write operation. Additionally, an input signal received from the inverter 811 is in the high logic state (e.g., “1”), such that the enable signal EN2 generated by the NOR gate 813 is in the low logic state (e.g., “0”). Accordingly, the operations of the word-line driver 820 for the write operation are similar to those described in the embodiments of FIGS. 2A to 2D, indicating that the voltage level of the output signal OUT, as shown by curve 838 in FIG. 8B is pulled up toward the power supply voltage V_{DD} from time tᵣ.

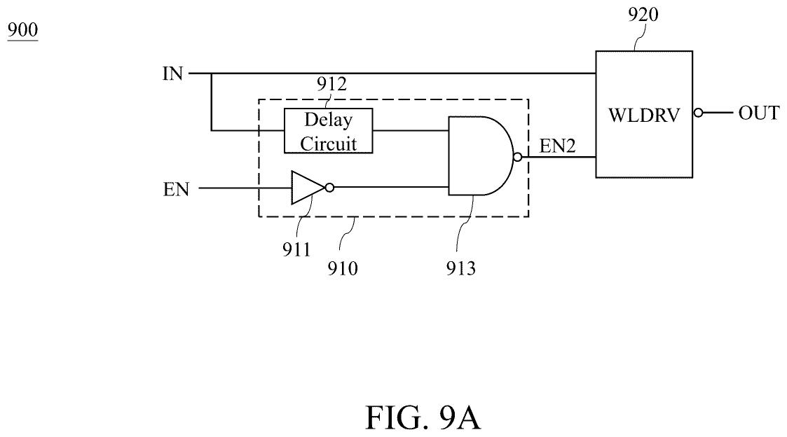

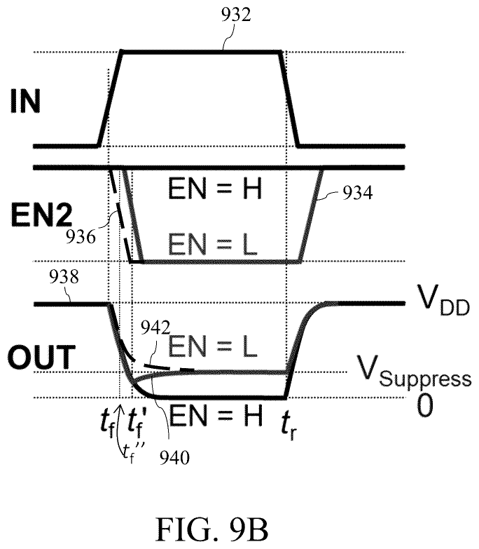

FIG. 9A is a block diagram of a word-line driver in accordance with still some embodiments of the present disclosure. FIG. 9B is a waveform diagram of various signals within the word-line driver in FIG. 9A.

In some embodiments, the word-line driver 121 shown in FIG. 1B can be implemented using the word-line driver 900 for use by an active-low word line of a memory cell, as shown in FIG. 9A. The word-line driver 900 includes a control circuit 910 and a word-line driver 920. The word-line driver 920 could be any of the word-line drivers 600A to 600D shown in FIGS. 6A to 6D. The control circuit 910 is configured to provide a sharper fall transition for the output signal OUT generated by the word-line driver 920. As shown in FIG. 9A, the control circuit 910 includes an inverter 911, a delay circuit 912, and a NAND gate 913. The delay circuit 912 may be implemented using an inverter chain, one or more buffers, or any other logically equivalent circuits. Additionally, the control circuit 910 can be implemented using any other logically equivalent circuits.

For example, when the enable signal EN is in the low logic state (e.g., “0”), it indicates that the word-line driver 900 is used for a read operation. The activation signal IN, as shown by curve 932 in FIG. 9B, switches from the low logic state (“0”) to the high logic state (“1”) at time tr. For brevity, the delay time caused by the delay circuit 912 is t_{f}′−t_{f} (e.g., for the overshoot case of the output signal OUT) or t_{f}″−t_{f} (e.g., for the overdamped case of the output signal OUT). Accordingly, the enable signal EN2, as shown by curves 934 or 936, generated by the NAND gate 913 is kept at the high logic state (e.g., “1”) until the delayed activation signal IN generated by the delay circuit 912 switches from the high logic state (“1”) to the low logic state (“0”) at time t_{f}′ for the overshoot case or at time t_{f}″ for the overdamped case, where time t_{f}″ is earlier than time t_{f}′.

Specifically, for the overshoot case of the output signal OUT, the delay circuit 912 can be designed to have a longer delay time, such as t_{f}′−t_{f}. This indicates that the enable signal EN2, as shown by curve 934 in FIG. 9B, received by the word-line driver 920 switches from the high logic state (e.g., “1”) to the low logic state (e.g., “0”) at time t_{f}′. Accordingly, the voltage level of the output signal OUT, as shown by curve 940 in FIG. 9B, is pulled down toward the reference voltage V_{SS} during the time interval between times t_{f} and t_{f}′, and it may be lower than the suppression voltage V_{Suppress} at time t_{f}′. At time t_{f}′, the voltage level of the output signal OUT is pulled up to and maintained at the suppression voltage V_{Suppress}.

For the overdamped case of the output signal OUT, the delay circuit 912 could be designed to have a shorter delay time, such as t_{f}″−t_{f}. This indicates that the enable signal EN2, as shown by curve 936 in FIG. 9B, received by the word-line driver 920 switches from the high logic state (e.g., “1”) to the low logic state (e.g., “0”) at time t_{f}“. Accordingly, the voltage level of the output signal OUT, as shown by curve 942 in FIG. 9B, is pulled down toward the reference voltage V_{SS} during the time interval between times tf and tf”, and it does not decrease to the suppression voltage V_{Suppress} at time t_{f}“. At time t_{f}”, the voltage level of the output signal OUT is pulled down and maintained at the suppression voltage V_{Suppress}. It should be noted that the delay time caused by the delay circuit 912 can be appropriately designed, such that the voltage level of the output signal OUT is exactly pulled down to the suppression voltage V_{Suppress} at time t_{f}′, avoiding the overshoot and overdamped conditions.

When the enable signal EN is in the high logic state (e.g., “1”), it indicates that the word-line driver 900 is used for a write operation. Additionally, an input signal received from the inverter 911 is in the low logic state (e.g., “0”), such that the enable signal EN2 generated by the NAND gate 913 is in the high logic state (e.g., “1”). Accordingly, the operations of the word-line driver 920 for the write operation are similar to those described in the embodiments of FIGS. 6A to 6D, indicating that the voltage level of the output signal OUT, as shown by curve 938 in FIG. 9B is pulled down toward the reference voltage V_{SS} from time t_{f}.

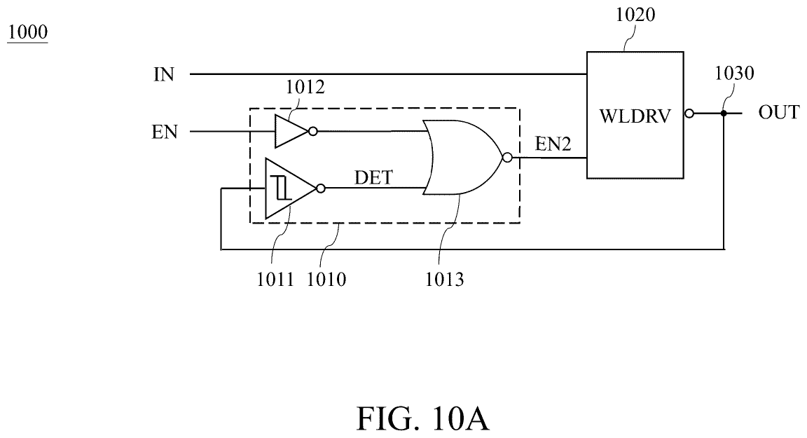

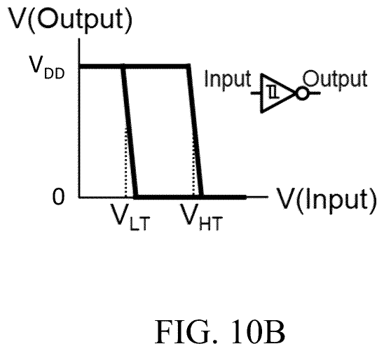

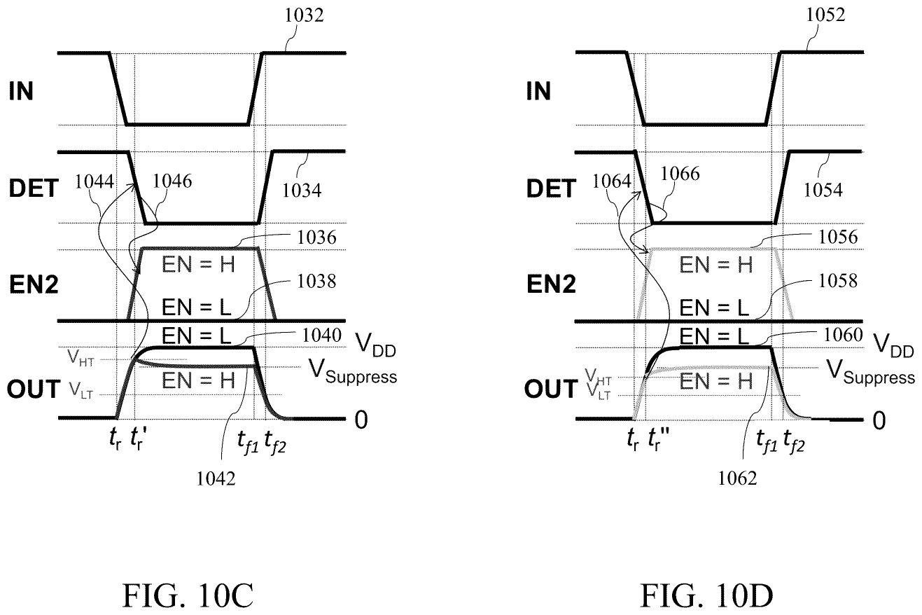

FIG. 10A is a block diagram of a word-line driver in accordance with still some embodiments of the present disclosure. FIG. 10B is a waveform of the Schmitt trigger 1011 in FIG. 10A. FIG. 10C is a waveform diagram of various signals within the word-line driver in FIG. 10A for the overshoot case. FIG. 10D is another waveform diagram of various signals within the word-line driver in FIG. 10A for the overdamped case.

In some embodiments, the word-line driver 121 shown in FIG. 1B can be implemented using the word-line driver 1000 for use by an active-high word line of a memory cell, as shown in FIG. 10A. The word-line driver 1000 includes a control circuit 1010 and a word-line driver 1020. The word-line driver 1020 could be any of the word-line drivers 200A to 200D shown in FIGS. 2A to 2D. The control circuit 1010 is configured to provide a sharper rise transition for the output signal OUT generated by the word-line driver 1020. As shown in FIG. 10A, the control circuit 1010 includes a Schmitt trigger 1011, an inverter 1012, and a NOR gate 1013. The control circuit 1010 may be implemented using any other logically equivalent circuits. In some embodiments, the Schmitt trigger 1011 is in an inverting configuration, which has a low trigger voltage V_{LT} and a high trigger voltage V_{HT}, as shown in FIG. 10B. For example, when the input voltage of the Schmitt trigger 1011 decreases from a high voltage to the low trigger voltage V_{LT}, the output voltage of the Schmitt trigger 1011 transitions from 0V to the power supply voltage V_{DD}. When the input voltage of the Schmitt trigger 1011 increases from a low voltage to the high trigger voltage V_{HT}, the output voltage of the Schmitt trigger 101 transitions from the power supply voltage V_{DD} to 0V, as shown in FIG. 10B.

Referring to FIG. 10C, in some embodiments, when the enable signal EN is in the high logic state (e.g., “1”), it indicates that the word-line driver 1000 is used for a read operation. For purposes of description, the output signal DET of the Schmitt trigger 1011 and the activation signal IN are initially in the high logic state (e.g., “1”), as shown by curves 1034 and 1032 in FIG. 10C, respectively. The activation signal IN switches from the high logic state (“1”) to the low logic state (“0”) at time tᵣ, such that the voltage level of the output signal OUT, as shown by curve 1042 in FIG. 10C, is pulled up toward the power supply voltage V_{DD} during the time interval between times tᵣ and tᵣ′. Once the voltage level of the output signal OUT reaches the high trigger voltage V_{HT} of the Schmitt trigger 1011 at time tᵣ′, the output signal DET of the Schmitt trigger 1011 switches from the high logic state (e.g., “1”) to the low logic state (e.g., “0”) at time tᵣ′, as shown by arrow 1044 in FIG. 10C. Since the high trigger voltage V_{HT} is higher than the suppression voltage V_{Suppress} (i.e., an overshoot case), the voltage level of the output signal OUT is pulled down from the high trigger voltage V_{HT} to the suppression voltage V_{Suppress} at time tᵣ′. Additionally, the low trigger voltage V_{LT} is lower than the suppression voltage V_{Suppress} to ensure that output signal OUT can be maintained at the suppression voltage V_{Suppress}, as shown by curve 1042. Because the output signal DET of the Schmitt trigger 1011 and the output signal of the inverter 1012 are both in the low logic state (e.g., “0”) at time tᵣ′, the enable signal EN2, as shown by curve 1036 in FIG. 10C, generated by the NOR gate 1013 switches from the low logic state (e.g., “0”) to the high logic state (e.g., “1”) at time tᵣ′, as shown by arrow 1046 in FIG. 10C.

Furthermore, the activation signal IN switches from the low logic state (e.g., “0”) to the high logic state (e.g., “1”) at time t_{f1}, such that the output signal OUT generated by the word-line driver 1020 switches from the high logic state (e.g., “1” or V_{Suppress}) to the low logic state (e.g., “0” or V_{SS}/GND). Once the voltage level of the output signal OUT decreases to the low trigger voltage V_{LT} of the Schmitt trigger 1011 at time t_{f2}, the output signal DET of the Schmitt trigger 1011 switches from the low logic state (e.g., “0”) to the high logic state (e.g. “1”) at time t_{f2}. Accordingly, the enable signal EN2 generated by the NOR gate 1013 switches from the high logic state (e.g., “1”) to the low logic state (e.g., “0”) at time t_{f2}.

When the enable signal EN is in the low logic state (e.g., “0”), it indicates that the word-line driver 1000 is used for a write operation. For purposes of description, the output signal DET of the Schmitt trigger 1011 and the activation signal IN are initially in the high logic state (e.g., “1”), as shown by curves 1034 and 1032 in FIG. 10C, respectively. It should be noted that because the output signal of the inverter 1012 is kept at the high logic state (e.g., “1”), the enable signal EN2, as shown by curve 1038 in FIG. 10C, generated by the NOR gate 1013 is kept at the low logic state (e.g., “0”). This indicates that the input enable signal EN2 of the word-line driver 1020 is kept at the low logic state (e.g., “0”) for the write operation, and thus the voltage level of the output signal OUT is pulled up toward the power supply voltage V_{DD} from time tr. Once the voltage level of the output signal OUT reaches the high trigger voltage V_{HT} of the Schmitt trigger 1011 at time tᵣ′, the output signal DET of the Schmitt trigger 1011 switches from the high logic state (e.g., “1”) to the low logic state (e.g., “0”) at time tᵣ′, as shown by arrow 1044 in FIG. 10C. It should be noted that when the voltage level of the output signal OUT increases to the power supply voltage V_{DD}, the voltage level of the output signal OUT is maintained at the power supply voltage V_{DD}.

Furthermore, the activation signal IN switches from the low logic state (e.g., “0”) to the high logic state (e.g., “1”) at time t_{f1}, such that the output signal OUT generated by the word-line driver 1020 switches from the high logic state (e.g., “1” or V_{DD}) to the reference voltage V_{SS} (e.g., 0V). Once the voltage level of the output signal OUT decreases to the low trigger voltage V_{LT} of the Schmitt trigger 1011 at time t_{f2}, the output signal DET of the Schmitt trigger 1011 switches from the low logic state (e.g., “0”) to the high logic state (e.g. “1”) at time t_{f2}. It should be noted that the enable signal EN2 (e.g., curve 1038) generated by the NOR gate 1013 is kept at the low logic state (e.g., “0”) all the time in FIG. 10C.

Referring to FIG. 10D, in some embodiments, when the enable signal EN is in the high logic state (e.g., “1”), it indicates that the word-line driver 1000 is used for a read operation. The operations of the activation signal IN, output signal DET, enable signal EN2, and output signal OUT in FIG. 10D, as shown by curves 1052, 1054, 1056, and 1062, are similar to curves 1032, 1034, 1036, and 1042 shown in FIG. 10C, respectively, with the difference being that the suppression voltage V_{Suppress} is higher than the high trigger voltage V_{HT} (i.e., an overdamped case), and the voltage level of the output signal OUT is pulled up from the high trigger voltage V_{HT} to the suppression voltage V_{Suppress} at time tᵣ″. Accordingly, the details for other operations of the signals in FIG. 10D are not repeated here.

When the enable signal EN is in the low logic state (e.g., “0”), it indicates that the word-line driver 1000 is used for a write operation. The operations of the activation signal IN, output signal DET, enable signal EN2, and output signal OUT in FIG. 10D, as shown by curves 1052, 1054, 1058, and 1060 in FIG. 10D, are similar to curves 1032, 1034, 1038, and 1040 shown in FIG. 10C, the details of which are not repeated here.

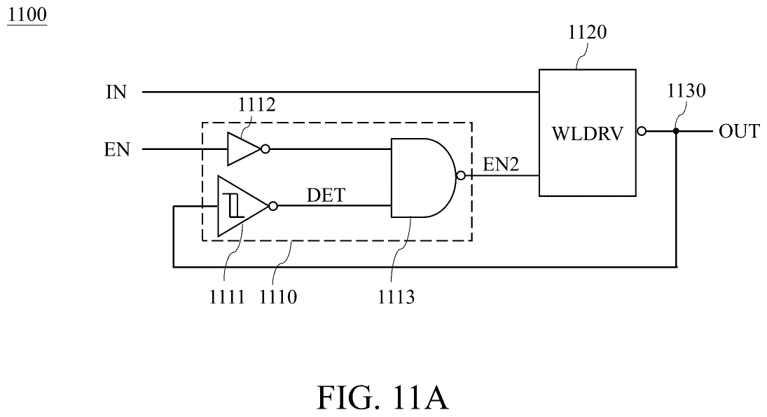

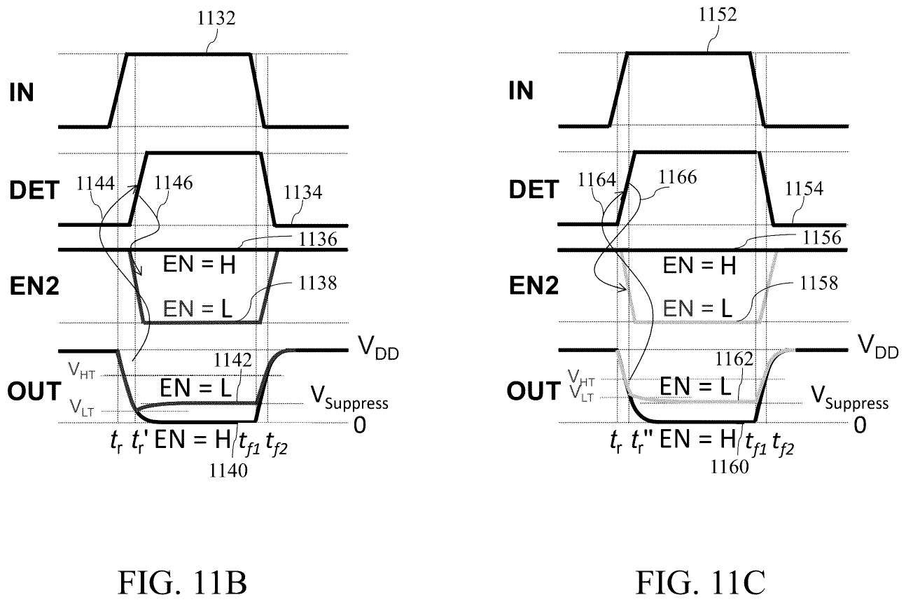

FIG. 11A is a block diagram of a word-line driver in accordance with still some embodiments of the present disclosure. FIG. 11B is a waveform diagram of various signals within the word-line driver in FIG. 11A for the overshoot case. FIG. 11C is another waveform diagram of various signals within the word-line driver in FIG. 11A for the overdamped case.

In some embodiments, the word-line driver 121 shown in FIG. 1B can be implemented using the word-line driver 1100 for use by an active-low word line of a memory cell, as shown in FIG. 11A. The word-line driver 1100 includes a control circuit 1110 and a word-line driver 1120. The word-line driver 1120 could be any of the word-line drivers 600A to 600D shown in FIGS. 6A to 6D. The control circuit 1110 is configured to provide a sharper fall transition for the output signal OUT generated by the word-line driver 1120. As shown in FIG. 11A, the control circuit 1110 includes a Schmitt trigger 1111, an inverter 1112, and a NAND gate 1113. The control circuit 1110 may be implemented using any other logically equivalent circuits. In some embodiments, the Schmitt trigger 1111 is in a non-inverting configuration, which has a low trigger voltage V_{LT} and a high trigger voltage V_{HT}, the details of which can be referred to the embodiment of FIG. 10B.

Referring to FIG. 11B, in some embodiments, when the enable signal EN is in the low logic state (e.g., “0”), it indicates that the word-line driver 1100 is used for a read operation. For purposes of description, the output signal DET of the Schmitt trigger 1111 and the activation signal IN are initially in the low logic state (e.g., “0”), as shown by curves 1134 and 1132 in FIG. 11B, respectively. The activation signal IN switches from the low logic state (“0”) to the high logic state (“1”) at time tᵣ, such that the voltage level of the output signal OUT, as shown by curve 1142 in FIG. 11B, is pulled down toward the reference voltage V_{SS} (e.g., 0V) during the time interval between times tᵣ and tᵣ′. Once the voltage level of the output signal OUT decreases to the low trigger voltage V_{LT} of the Schmitt trigger 1111 at time tᵣ′, the output signal DET of the Schmitt trigger 1111 switches from the low logic state (e.g., “0”) to the high logic state (e.g., “1”) at time tᵣ′, as shown by arrow 1144 in FIG. 11B. Since the low trigger voltage V_{LT} is lower than the suppression voltage V_{Suppress} (i.e., an overshoot case), the voltage level of the output signal OUT is pulled up from the low trigger voltage V_{LT} to the suppression voltage V_{Suppress} at time tᵣ′. Additionally, the high trigger voltage V_{HT} is higher than the suppression voltage V_{Suppress} to ensure that output signal OUT can be maintained at the suppression voltage V_{Suppress}, as shown by curve 1142. Because the output signal DET of the Schmitt trigger 1111 and the output signal of the inverter 1112 are both in the high logic state (e.g., “0”) at time tᵣ′, the enable signal EN2, as shown by curve 1138 in FIG. 11B, generated by the NAND gate 1113 switches from the high logic state (e.g., “1”) to the low logic state (e.g., “0”) at time tᵣ′, as shown by arrow 1146 in FIG. 11B.

Furthermore, the activation signal IN switches from the high logic state (e.g., “1”) to the low logic state (e.g., “0”) at time t_{f1}, such that the output signal OUT generated by the word-line driver 1120 switches from the low logic state (e.g., “0” or V_{Suppress}) to the high logic state (e.g., “1” or V_{DD}). Once the voltage level of the output signal OUT increases to the high trigger voltage V_{HT} of the Schmitt trigger 1111 at time t_{f2}, the output signal DET of the Schmitt trigger 1111 switches from the high logic state (e.g. “1”) to the low logic state (e.g., “0”) at time t_{f2}. Accordingly, the enable signal EN2 generated by the NAND gate 1113 switches from the low logic state (e.g., “0”) to the high logic state (e.g., “1”) at time t_{f2}.

When the enable signal EN is in the high logic state (e.g., “1”), it indicates that the word-line driver 1100 is used for a write operation. For purposes of description, the output signal DET of the Schmitt trigger 1111 and the activation signal IN are initially in the low logic state (e.g., “0”), as shown by curves 1134 and 1132 in FIG. 11B, respectively. It should be noted that because the output signal of the inverter 1112 is kept at the low logic state (e.g., “0”), the enable signal EN2, as shown by curve 1136 in FIG. 11B, generated by the NAND gate 1113 is kept at the high logic state (e.g., “1”). This indicates that the input enable signal EN2 of the word-line driver 1020 is kept at the high logic state (e.g., “1”) for the write operation, and thus the voltage level of the output signal OUT is pulled down toward the reference voltage V_{SS} from time tr. Once the voltage level of the output signal OUT decreases to low trigger voltage V_{LT} of the Schmitt trigger 1111 at time tᵣ′, the output signal DET of the Schmitt trigger 1111 switches from the low logic state (e.g., “0”) to the high logic state (e.g., “1”) at time tᵣ′, as shown by arrow 1144 in FIG. 11B. It should be noted that when the voltage level of the output signal OUT decreases to the reference voltage V_{SS} (e.g., 0V), the voltage level of the output signal OUT is maintained at the reference voltage V_{SS}.

Furthermore, the activation signal IN switches from the high logic state (e.g., “1”) to the low logic state (e.g., “0”) at time t_{f1}, such that the output signal OUT generated by the word-line driver 1120 switches from the low logic state (e.g., “0” or V_{Suppress}) to the high logic state (e.g., V_{DD}). Once the voltage level of the output signal OUT increases to the high trigger voltage V_{HT} of the Schmitt trigger 1111 at time t_{f2}, the output signal DET of the Schmitt trigger 1011 switches from the high logic state (e.g. “1”) to the low logic state (e.g., “0”) at time t_{f2}. It should be noted that the enable signal EN2 (e.g., curve 1136) generated by the NAND gate 1113 is kept at the high logic state (e.g., “1”) all the time in FIG. 11B.

Referring to FIG. 11C, in some embodiments, when the enable signal EN is in the low logic state (e.g., “0”), it indicates that the word-line driver 1000 is used for a read operation. The operations of the activation signal IN, output signal DET, enable signal EN2, and output signal OUT in FIG. 11C, as shown by curves 1152, 1154, 1158, and 1162, are similar to curves 1132, 1134, 1138, and 1142 shown in FIG. 11B, respectively, with the difference being that the suppression voltage V_{Suppress} is lower than the low trigger voltage V_{LT} (i.e., an overdamped case), and the voltage level of the output signal OUT is pulled down from the low trigger voltage V_{LT} to the suppression voltage V_{Suppress} at time tᵣ″. Accordingly, the details for other operations of the signals in FIG. 11C during a read operation are not repeated here.

When the enable signal EN is in the high logic state (e.g., “1”), it indicates that the word-line driver 1100 is used for a write operation. The operations of the activation signal IN, output signal DET, enable signal EN2, and output signal OUT in FIG. 11C, as shown by curves 1152, 1154, 1156, and 1160 in FIG. 11C, are similar to curves 1132, 1134, 1136, and 1140 shown in FIG. 11B, the details of which are not repeated here.

In some embodiments, regarding word-line drivers 800A and 1000A in FIGS. 8A and 10A, which utilize the word-line driver 200A in FIG. 2A, the driving capabilities of transistors P0 to P2 and N0 to N2 may be designed appropriately to suppress the crowbar current, while maintaining rise and fall transition speed. In some embodiments, the driving capabilities of transistors P1, N1 and N2 are lower than those of transistors P0, P2 and N0 in the word-line driver 200A to suppress the crowbar current during the read operation and to maintain sufficient transition speed. For example, when the enable signal EN2 is in the high logic state (e.g., “1”) and the activation signal IN is in the low logic state (e.g., “0”), the crowbar current passes through transistors P0, P1, N0, and N1. On the other hand, when the enable signal EN2 is in the low logic state (e.g., “0”) or the activation signal IN is in the high logic state (e.g., “1”), transition speeds are determined by driving capabilities of transistors P0, P2 and N0. Accordingly, the driving capabilities of transistors P1, N1, and N2 are lower than those of transistors P0, P2, and N0 to suppress the crowbar current, while the rise and fall transition speed are maintained. Here, the driving capabilities of transistors P0 to P2 and N0 to N2 may refer to the transistor sizes (e.g., W/L ratio for planar FETs, the number of fingers for finFETs, or number of sheets for nanosheet FETs) or the threshold voltages (i.e., in their magnitude or absolute value) thereof. The relationships between driving capabilities of transistors P0 to P2 and N0 and N2 within the word-line drivers 200B to 200D in FIGS. 2B to 2D can be designed in a manner similar to the word-line driver 200A.

In some embodiments, regarding word-line drivers 900A and 1100A in FIGS. 9A and 11A, which utilize the word-line driver 600A in FIG. 6A, the driving capabilities of transistors P10 to P12 and N10 to N12 may be designed appropriately to suppress the crowbar current, while maintaining rise and fall transition times. In some embodiments, the driving capabilities of transistors N11, P11, and P12 are lower than those of transistors N10, N12, and P10 in the word-line driver 600A to suppress the crowbar current during the read operation and to maintain sufficient transition speed. For example, when the enable signal EN2 is in the low logic state (e.g., “0”) and the activation signal IN is in the low logic state (e.g., “1”), the crowbar current passes through transistors P12, P11, N11, and N10. On the other hand, when the enable signal EN2 is in the high logic state (e.g., “1”) or the activation signal IN is in the low logic state (e.g., “0”), transition speeds are determined by driving capabilities of transistors P10, N12 and N10. Accordingly, the driving capabilities of transistors N11, P11, and P12 are lower than those of transistors N10, N12, and P10 to suppress the crowbar current, while the rise and fall transition speed are maintained. Here, the driving capabilities of transistors P10 to P12 and N10 to N12 may refer to the transistor sizes (e.g., W/L ratio for planar FETs, the number of fingers for finFETs, or number of sheets for nanosheet FETs) or the threshold voltages (i.e., in their magnitude or absolute value) thereof. The relationships between driving capabilities of transistors P10 to P12 and N10 and N12 within the word-line drivers 600B to 600D in FIGS. 6B to 6D can be designed in a manner similar to the word-line driver 600A.

It should be noted that although the memory cell 300 shown in FIG. 3A and memory cell 700 shown in FIG. 7A are 6-transistor static random access memory (6T-SRAM) cells, the present disclosure is not limited to SRAM cells. The technique for suppressing the word-line voltage for read assist described in the present disclosure can also be applied to other types of memory cells with a word line and pass gates, such as dynamic random access memory (DRAM) cells, flash memory cells, electrically erasable programmable read-only memory (EEPROM), ferroelectric RAM (FeRAM), magnetoresistive RAM (MRAM), phase-change memory (PCM), and the like.

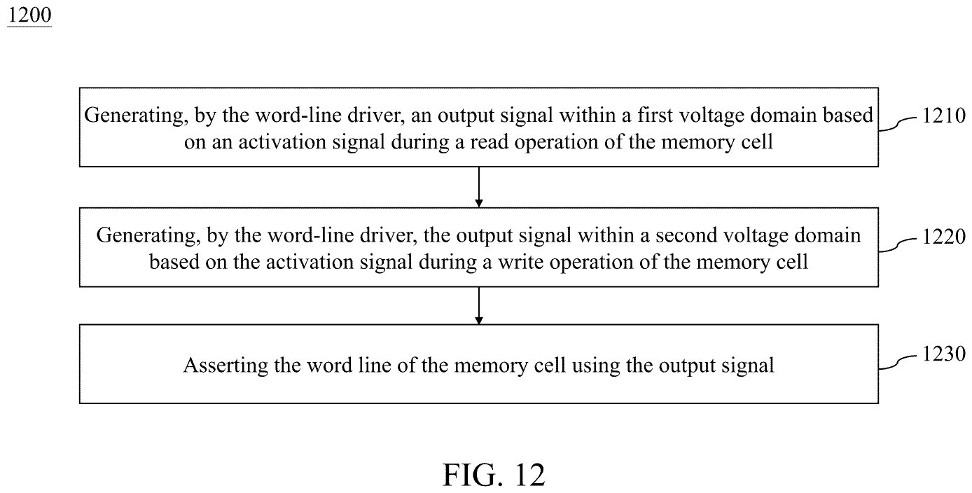

FIG. 12 is a flowchart of a method for operating a word-line driver in accordance with some embodiments of the present disclosure. The method 1200 includes operations 1210 to 1230.

At operation 1210, an output signal within a first voltage domain is generated by the word-line driver based on an activation signal during a read operation of the memory cell. In some embodiments, when the enable signal EN2 is in the high logic state and the low logic state, any of the word-line drivers 200A to 200D may perform a read operation and a write operation on the memory cell with an active-high word line coupled to the output terminal thereof, respectively. Additionally, the pass gates within the memory cell (e.g., memory cell 300 in FIG. 3A) has a positive threshold voltage. In some other embodiments, when the enable signal EN2 is in the low logic state and the high logic state, any of the word-line drivers 600A to 600D may perform a read operation and a write operation on the memory cell with an active-low word line coupled to the output terminal thereof, respectively. Additionally, the pass gates within the memory cell (e.g., memory cell 700 in FIG. 7A) has a negative threshold voltage.

At operation 1220, the output signal within a second voltage domain is generated by the word-line driver based on the activation signal during a write operation of the memory cell. In some embodiments, the first voltage domain is between the reference voltage V_{SS} and the suppression voltage V_{Suppress}, while the second voltage domain is between the reference voltage V_{SS} and the power supply voltage V_{DD} for memory cells with a high-active word line. In some other embodiments, the first voltage domain is between the power supply voltage V_{DD} and the suppression voltage V_{Suppress}, while the second voltage domain is between the power supply voltage V_{DD} and the reference voltage V_{SS} for memory cells with a low-active word line.

At operation 1230, the word line of the memory cell is asserted using the output signal, wherein the second voltage domain is wider than the first voltage domain. In some embodiments, the voltage level of the output signal generated by the word-line driver, which serves as the voltage of the word line of the memory cell, is suppressed to swing within the first voltage domain during the read operation, thereby reducing power consumption during the read operation. Conversely, the voltage level of the output signal generated by the word-line driver swings within the second voltage domain which is wider than the first voltage domain.

An aspect of the present disclosure provides a word-line driver which includes an input stage, a driving stage, a supplementary voltage pull-up device, and a supplementary voltage pull-down device. The input stage receives an activation signal. The driving stage is coupled to the input stage and an output terminal of the word-line driver, and is configured to generate an output signal at the output terminal. The supplementary voltage pull-up device is coupled to the input stage and the driving stage, and is configured to pull up the output signal to a power supply voltage in response to a first enable signal being in a first logic state. The supplementary voltage pull-down device is coupled to the input stage and the driving stage, and is configured to pull down the output signal to a reference voltage in response to the first enable signal being in a second logic state complementary to the first logic state. The output signal swings within a first voltage domain in response to the first enable signal being in the first logic state, and swings within a second voltage domain in response to the first enable signal being in the second logic state. The second voltage domain is wider than the first voltage domain.

Another aspect of the present disclosure provides a word-line driver which includes an input stage, a driving stage, a supplementary voltage pull-up device, and a supplementary voltage pull-down device. The input stage receives an activation signal. The driving stage is coupled to the input stage and an output terminal of the word-line driver, and it is configured to generate an output signal at the output terminal. The supplementary voltage pull-up device is coupled to the input stage and the driving stage, and it is configured to pull up the output signal to a power supply voltage during a write operation performed by the word-line driver. The supplementary voltage pull-down device is coupled to the input stage and the driving stage, and it is configured to pull down the output signal to a reference voltage during a read operation performed by the word-line driver. The output signal swings within a first voltage domain during the read operation, and swings within a second voltage domain during the write operation. The second voltage domain is wider than the first voltage domain.

Yet another aspect of the present disclosure provides a method for operating a word-line driver for use with a word line of a memory cell. The method includes the following steps: generating, by the word-line driver, an output signal within a first voltage domain based on an activation signal during a read operation of the memory cell; generating, by the word-line driver, the output signal within a second voltage domain based on the activation signal during a write operation of the memory cell; and asserting the word line of the memory cell using the output signal. The second voltage domain is wider than the first voltage domain.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A word-line driver, comprising:
an input stage, receiving an activation signal;
a driving stage, coupled to the input stage and an output terminal of the word-line driver, and configured to generate an output signal at the output terminal;
a supplementary voltage pull-up device, coupled to the input stage and the driving stage, and configured to pull up the output signal to a power supply voltage in response to a first enable signal being in a first logic state; and
a switch device, coupled to the input stage and the driving stage, and configured to pull down the output signal to a reference voltage in response to the first enable signal being in a second logic state complementary to the first logic state,
wherein the output signal swings within a first voltage domain in response to the first enable signal being in the first logic state, and swings within a second voltage domain in response to the first enable signal being in the second logic state,
wherein the second voltage domain is wider than the first voltage domain.

2. The word-line driver of claim 1, wherein the output terminal of the word-line driver is coupled to a word line of a memory cell.

3. The word-line driver of claim 2, wherein:
the word line of the memory cell is an active-high word line;
the first voltage domain is between the reference voltage and a suppression voltage;
the second voltage domain is between the reference voltage and the power supply voltage; and
the power supply voltage is higher than the suppression voltage.

4. The word-line driver of claim 3, wherein:
in response to the first enable signal being in the first logic state, the word-line driver is configured to perform a read operation on the memory cell; and
in response to the first enable signal being in the second logic state, the word-line driver is configured to perform a write operation on the memory cell;
the memory cell comprises one or more pass gates with a positive threshold voltage; and
the suppression voltage is higher than the positive threshold voltage.

5. The word-line driver of claim 4, wherein when the first enable signal is in the first logic state, a voltage level of the output signal is pulled up from the reference voltage to the suppression voltage in response to the activation signal switching from the first logic state to the second logic state, and is pulled down from the suppression voltage to the reference voltage in response to the activation signal switching from the second logic state to the first logic state.

6. The word-line driver of claim 5, further comprising: a control circuit, which comprises:
a delay circuit, configured to delay the activation signal to generate a delayed activation signal;
an inverter; configured to invert a second enable signal to generate an inverted second enable signal; and
a NOR gate, configured to receive the delayed activation signal and the inverted second enable signal to generate the first enable signal.

7. The word-line driver of claim 5, further comprising: a control circuit, which comprises:
an inverter, configured to invert a second enable signal to generate an inverted second enable signal;
a Schmitt trigger, configured to generate a first voltage signal based on the output signal generated by the word-line driver; and
a NOR gate, configured to receive the inverted second enable signal and the first voltage signal to generate the first enable signal.

8. The word-line driver of claim 7, wherein:
the Schmitt trigger operates in an inverting configuration with a high trigger voltage and a low trigger voltage;
in response to the voltage level of the output signal decreasing to the low trigger voltage, the first voltage signal generated by the Schmitt trigger switches from a low logic state to a high logic state;
in response to the voltage level of the output signal increasing to the high trigger voltage, the first voltage signal generated by the Schmitt trigger switches from the high logic state to the low logic state; and
the low trigger voltage is lower than the suppression voltage.

9. The word-line driver of claim 2, wherein:
the word line of the memory cell is an active-low word line;
the first voltage domain is between the power supply voltage and a suppression voltage;
the second voltage domain is between the power supply voltage and the reference voltage; and
the power supply voltage is higher than the suppression voltage.

10. The word-line driver of claim 9, wherein:
in response to the first enable signal being in the first logic state, the word-line driver is configured to perform a read operation on the memory cell;
in response to the first enable signal being in the second logic state, the word-line driver is configured to perform a write operation on the memory cell;
the memory cell comprises one or more pass gates with a negative threshold voltage; and
a difference between the suppression voltage and the power supply voltage is lower than the negative threshold voltage.

11. The word-line driver of claim 10, wherein when the first enable signal is in the first logic state, a voltage level of the output signal is pulled down from the power supply voltage to the suppression voltage in response to the activation signal switching from the first logic state to the second logic state, and is pulled up from the suppression voltage to the power supply voltage in response to the activation signal switching from the second logic state to the first logic state.

12. The word-line driver of claim 11, further comprising: a control circuit, which comprises:
a delay circuit, configured to delay the activation signal to generate a delayed activation signal;
an inverter; configured to invert a second enable signal to generate an inverted second enable signal; and
a NAND gate, configured to receive the delayed activation signal and the inverted second enable signal to generate the first enable signal.

13. The word-line driver of claim 11, further comprising: a control circuit, which comprises:
an inverter, configured to invert a second enable signal to generate an inverted second enable signal;
a Schmitt trigger, configured to generate a first voltage signal based on the output signal generated by the word-line driver; and
a NAND gate, configured to receive the inverted second enable signal and the first voltage signal to generate the first enable signal.

14. The word-line driver of claim 13, wherein:
the Schmitt trigger operates in an inverting configuration with a high trigger voltage and a low trigger voltage;
in response to the voltage level of the output signal decreases to the low trigger voltage, the first voltage signal generated by the Schmitt trigger switches from a low logic state to a high logic state;
in response to the voltage level of the output signal increases to the high trigger voltage, the first voltage signal generated by the Schmitt trigger switches from the high logic state to the low logic state; and
the high trigger voltage is higher than the suppression voltage.

15. A word-line driver, comprising:
an input stage, receiving an activation signal;
a driving stage, coupled to the input stage and an output terminal of the word-line driver, and configured to generate an output signal at the output terminal;
a switch device, coupled to the input stage and the driving stage, and configured to pull up the output signal to a power supply voltage during a write operation performed by the word-line driver; and
a supplementary voltage pull-down device, coupled to the input stage and the driving stage, and configured to operate in conjunction with the driving stage to pull down the output signal to a reference voltage during a read operation performed by the word-line driver,
wherein the output signal swings within a first voltage domain during the read operation, and swings within a second voltage domain during the write operation,
wherein the second voltage domain is wider than the first voltage domain.

16. The word-line driver of claim 15, wherein driving capabilities of the switch device and a first transistor and a second transistor within the driving stage and are lower than those of the supplementary voltage pull-down device and a third transistor and a fourth transistor within the input stage.

17. The word-line driver of claim 15, wherein the driving capabilities comprise transistor sizes and/or threshold voltages.

18. The word-line driver of claim 16, wherein the transistor size of each transistor refers a ratio of a channel width to a channel length for each transistor implemented using a planar field-effect transistor (FET), refer to a number of fingers for each transistor implemented using a finFET, or refer to a number of sheets for each transistor implemented using a nanosheet FETs.

19. A method for operating a word-line driver, which is coupled to a word line of a memory cell, the method comprising:
generating, by the word-line driver, an output signal within a first voltage domain based on an activation signal during a read operation of the memory cell;
generating, by the word-line driver, the output signal within a second voltage domain based on the activation signal during a write operation of the memory cell; and
asserting the word line of the memory cell using the output signal,
wherein the second voltage domain is wider than the first voltage domain.

20. The method of claim 19, wherein:
the first voltage domain is between a reference voltage and a suppression voltage;
the second voltage domain is between the reference voltage and a power supply voltage; and
the power supply voltage is higher than the suppression voltage.
